(19) United States
(12) Patent Application Publication
(10) Pub. No.: US 2008/0233730 A1
(43) Pub. Date: Sep. 25, 2008

(54) Method for fabricating semiconductor device

(75) Inventors: Jae-Seon Yu, Kyoungki-do (KR); Sang-Rok Oh, Kyoungki-do (KR)

Correspondence Address: BLAKELY SOKOLOFF TAYLOR & ZAFMAN LLP, 1279 OAKMEAD PARKWAY, SUNNYVALE, CA, 94085-4040, US

(73) Assignee: Hynix Semiconductor Inc.

(21) Appl. No.: 12/005,565

(22) Filed: Dec. 27, 2007

(30) Foreign Application Priority Data
Mar. 23, 2007 (KR) 2007-0028683

(51) Int. Cl. H01L 21/3205; G03F 7/26

(52) U.S. Cl. 438/596; 430/313; 257/E21.294

(57) ABSTRACT

A method for fabricating a semiconductor device includes providing a substrate where a cell region and a peripheral region are defined, stacking a conductive layer, a hard mask layer, a metal-based hard mask layer, and an amorphous carbon (C) pattern over the substrate etching the metal-based hard mask layer using the amorphous C pattern as an etch mask, thereby forming a resultant structure, forming a photoresist pattern covering the resultant structure in the cell region while exposing the resultant structure in the peripheral region, decreasing a width of the etched metal-based hard mask layer in the peripheral region, removing the photoresist pattern and the amorphous C pattern, and forming a conductive pattern by etching the hard mask layer and the conductive layer using the etched metal-based hard mask layer as an etch mask.

### CROSS-REFERENCE TO RELATED APPLICATIONS

The present invention claims priority of Korean patent application number 2007-0028683, filed on Mar. 23, 2007, which is incorporated by reference in its entirety.

### BACKGROUND OF THE INVENTION

The present invention relates to a method for fabricating a semiconductor device, and more particularly, to a method for fabricating a semiconductor device to adjust a critical dimension (CD) of a gate pattern in a peripheral region. As it is well known, as semiconductor devices become more highly integrated, a CD of a gate pattern decreases.

FIG. 1 is a cross-sectional view of a typical method for fabricating a semiconductor device.

Referring to FIG. 1, a gate oxide layer 102, a polysilicon layer 103, and a tungsten (W) layer 104 are sequentially stacked over a substrate 101. Although it is not shown, a gate hard mask nitride layer is formed over the W layer 104. The gate hard mask nitride layer is patterned by a mask pattern 106. The patterned gate hard mask nitride layer in a cell region is a first gate hard mask pattern 105A and the patterned gate hard mask nitride layer in a peripheral region is a second gate hard mask pattern 105B.

As described above, in the typical method, the gate hard mask layer is formed over the W layer to form a gate hard mask pattern. The mask pattern 106 is formed over the gate hard mask layer to define CDs of gate patterns which are respectively required in the cell region and the peripheral region. The gate hard mask nitride layers in the cell region and the peripheral region are simultaneously etched so that the first gate hard mask pattern 105A and the second gate hard mask pattern 105B are formed.

However, the typical method causes an etch loading due to a pattern density gap between the cell region and the peripheral region. The gate hard mask nitride layer in the peripheral region is etched while having a slope profile S so that a development inspection CD (DICD) is greater than a final inspection CD (FICD) in the mask pattern 106. That is, since polymers are not completely released in the peripheral region having a lower density than the cell region, an increased loading effect increases a FICD bias.

As a result, the DICD of the peripheral region should be decreased as much as an etch bias, i.e., as much as the FICD in the cell region increased. However, if the DICD of the peripheral region decreases, an exposure margin of the mask pattern 106 decreases. Thus, a pattern fail, e.g. a pattern collapse, may be caused.

Particularly, since, according to a decrease of a design rule and a required FICD of the peripheral region, a required DICD should also be decreased as much as the etch bias, it is difficult to secure the exposure margin of the mask pattern 106 and form a pattern.

### SUMMARY OF THE INVENTION

Embodiments of the present invention are directed to provide a method for fabricating a semiconductor device for adjusting a critical dimension (CD) of a gate pattern in a peripheral region.

In accordance with an aspect of the present invention, there is provided a method for fabricating a semiconductor device. The method includes providing a substrate where a cell region and a peripheral region are defined, stacking a conductive layer, a hard mask layer, a metal-based hard mask layer, and an amorphous carbon (C) pattern over the substrate etching the metal-based hard mask layer using the amorphous C pattern as an etch mask, thereby forming a resultant structure, forming a photoresist pattern covering the resultant structure in the cell region while exposing the resultant structure in the peripheral region, decreasing a width of the etched metal-based hard mask layer in the peripheral region, removing the photoresist pattern and the amorphous C pattern, and forming a conductive pattern by etching the hard mask layer and the conductive layer using the etched metal-based hard mask layer as an etch mask.

### BRIEF DESCRIPTION OF THE DRAWINGS

FIG. 1 is a cross-sectional view of a typical method for fabricating a semiconductor device.

FIGS. 2A to 2E are cross-sectional views of a method for fabricating a semiconductor device in accordance with a first embodiment of the present invention.

FIGS. 3A to 3F are cross-sectional views of a method for fabricating a semiconductor device in accordance with a second embodiment of the present invention.

FIG. 4 is a cross-sectional view of a method for fabricating a semiconductor device in accordance with a third embodiment of the present invention.

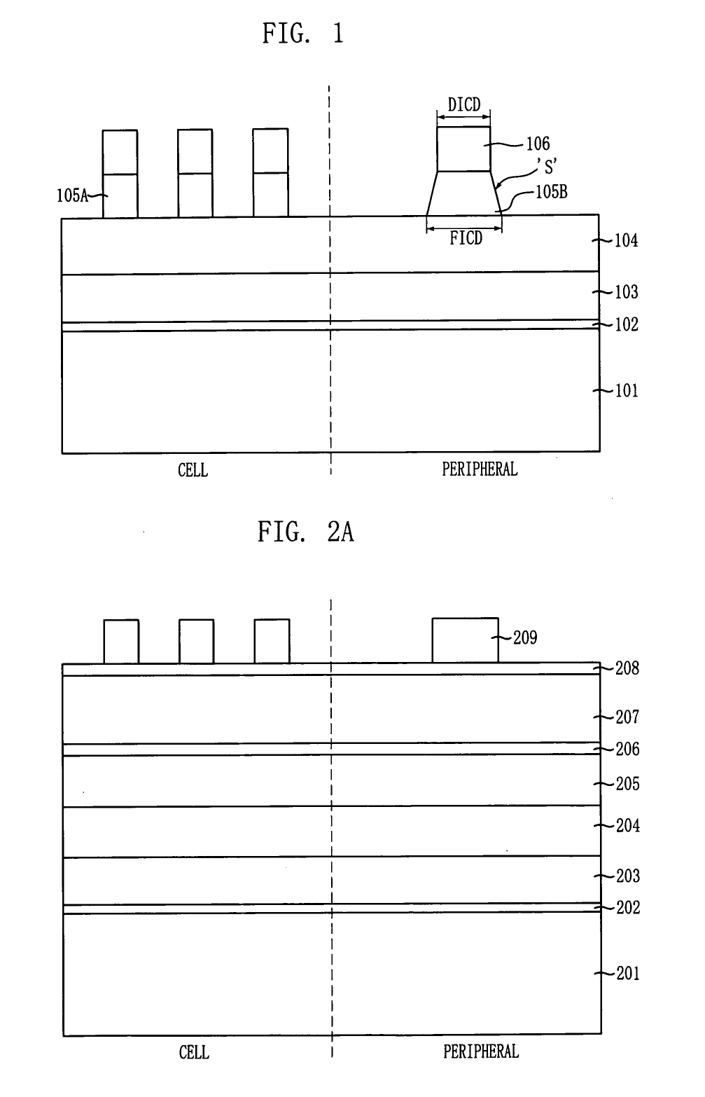

### DESCRIPTION OF SPECIFIC EMBODIMENTS

Embodiments of the present invention relate to a method for fabricating a semiconductor device.

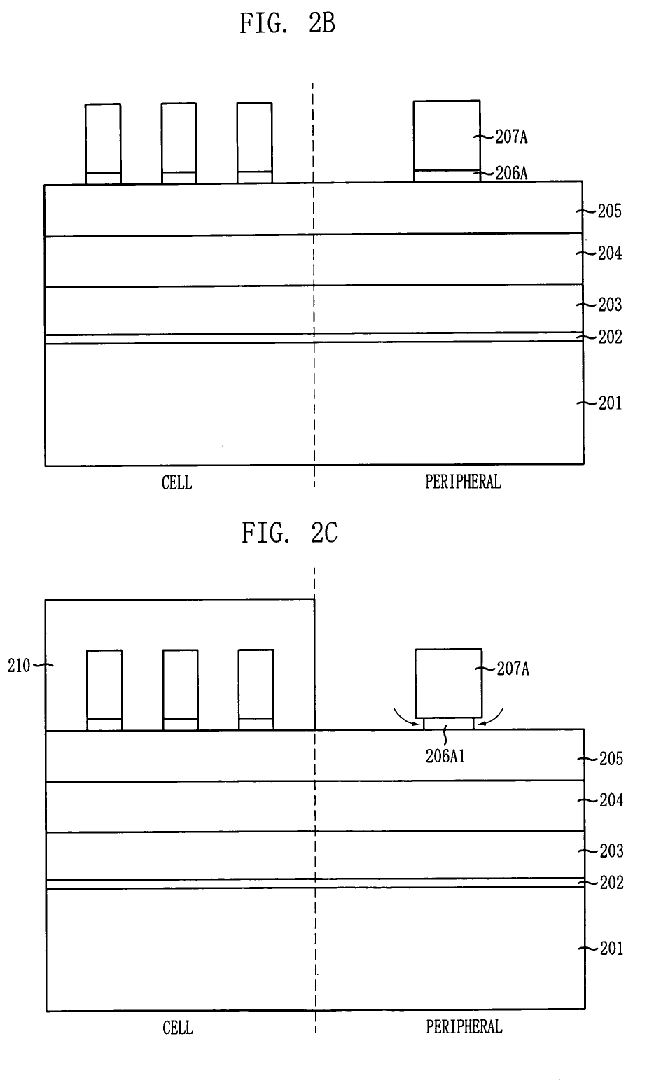

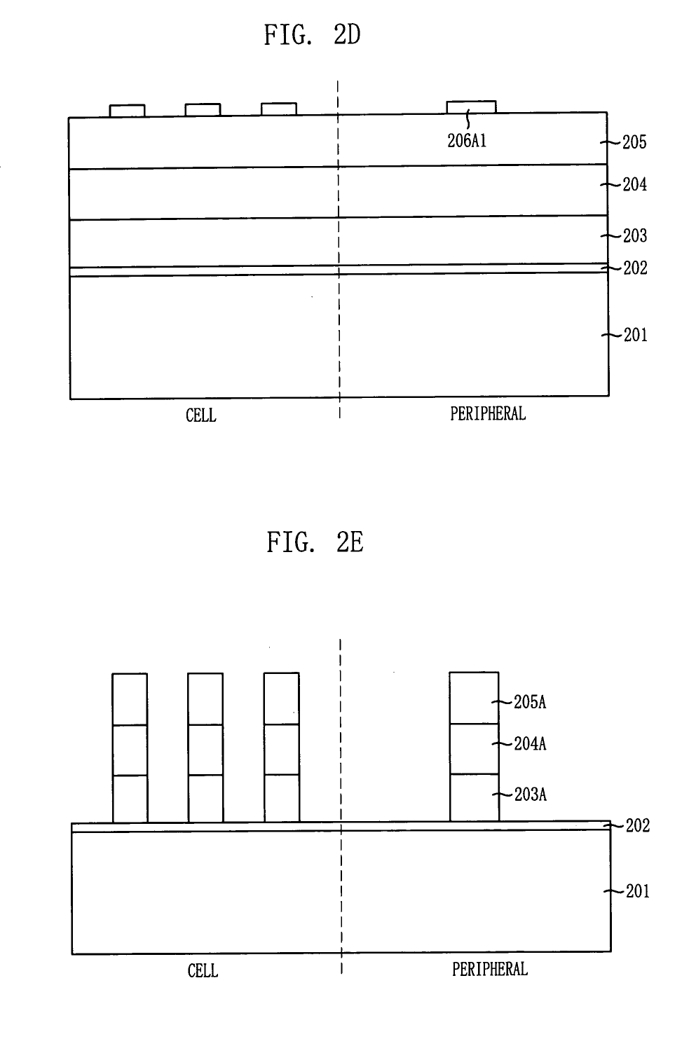

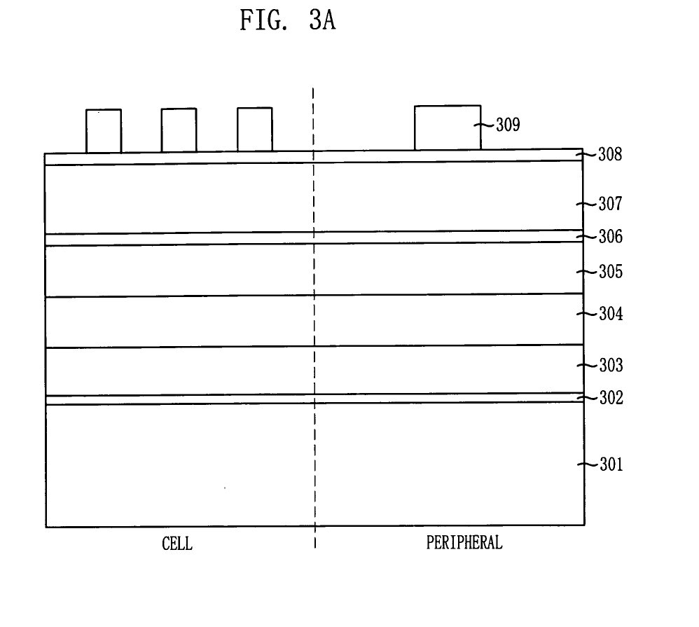

FIGS. 2A to 2E are cross-sectional views of a method for fabricating a semiconductor device in accordance with a first embodiment of the present invention.

Referring to FIG. 2A, a gate insulation layer 202 is formed over a substrate 201 including a cell region and a peripheral region. The substrate 201 may include a semiconductor substrate on which a dynamic random access memory (DRAM) process is to be performed. The gate insulation layer 202 may include an oxide layer. The oxide layer may be a thermal oxide layer or a plasma oxide layer.

A polysilicon layer 203 is formed over the gate insulation layer 202. A conductive layer 204 for an electrode is formed over the polysilicon layer 203. The conductive layer 204 includes a metal layer or a metal silicide layer. The metal layer includes one selected from a group consisting of tungsten (W), titanium nitride (TiN), and tungsten nitride (WN) layers. The metal silicide layer includes a tungsten silicide (WSix) layer.

A gate hard mask layer 205 is formed over the conductive layer 204. The gate hard mask layer 205 includes a nitride layer.

A metal-based hard mask layer 206 is formed over the gate hard mask layer 205. The metal-based hard mask layer 206 includes one of W, Ti/TiN, titanium tetrachloride (TiCl₄), WN, WSiX, and alumina (Al₂O₃) layers. The metal-based hard mask layer 206 is the W layer in this embodiment.

A C layer 207 and an anti-reflective coating (ARC) layer 208 are formed over the metal-based hard mask layer 206. A first photoresist pattern 209 is formed over the ARC layer 208 to define gate pattern formation regions. The ARC layer 208 includes a silicon oxy-nitride (SiON) layer and prevents a reflection when forming the first photoresist pattern 209. The first photoresist pattern 209 is formed by coating a photoresist layer over the ARC layer 208 and then patterning the photoresist layer by using a photo-exposure and development process to define the gate pattern formation regions in the cell region and the peripheral region.

Referring to FIG. 2B, the ARC layer 208, the amorphous C-layer 207, and the metal-based hard mask layer 206 are sequentially etched.

By using the first photoresist pattern 209, the ARC layer 208 and the amorphous C layer 207 are etched. A gas mixture of oxygen (O₂), nitrogen (N₂), and hydrogen (H₂) is used for this etch process. When the amorphous C layer 207 is etched, the photoresist layer is also etched by the gas mixture of O₂, N₂, and H₂. Thus, the first photoresist pattern 209 is completely removed when the above process of etching the amorphous C layer 207 is completed. Hereinafter, the etched amorphous C layer 207 is called an amorphous C pattern 207A.

Subsequently, the metal-based hard mask layer 206 is etched by using the amorphous C pattern 207A. A sulfur hexafluoride (SF₆) gas or a tetrafluoromethane (CF₄) gas is used for this etch process. Since the SF₆ gas or the CF₄ gas etches a SiON layer, the ARC layer 208 is completely removed when the process of etching the metal-based hard mask layer 206 is completed. Hereinafter, the etched metal-based hard mask layer 206 is called a metal-based hard mask pattern 206A.

As the first photoresist pattern 209 and the ARC layer 208 are completely removed, only the amorphous C-pattern 207A and the metal-based hard mask pattern 206A remain over the gate hard mask layer 205.

Referring to FIG. 2C, a second photoresist pattern 210 is formed to cover a resultant structure in the cell region described in FIG. 2B while exposing the peripheral region. The second photoresist pattern 210 is formed by coating a photoresist layer over a top surface of a resultant structure described in FIG. 2B and then patterning the photoresist layer by using a photo-exposure and development process to leave the photoresist layer only in the cell region.

Then, a process is performed to decrease a CD of the metal-based hard mask pattern 206A in the peripheral region. This is accomplished by wet-etching or dry etching a sidewall of the metal-based hard mask pattern 206A.

The wet-etch process is performed using an ammonium hydroxide-peroxide mixture (APM) solution. The APM solution includes ammonia water (NH₄OH), hydrogen peroxide (H₂O₂), and water (H₂O) mixed at a ratio of approximately 1:1:5, approximately 1:4:20 or approximately 1:5:50 and has a temperature ranging from approximately 21° C. to approximately 100° C.

The dry-etch process is performed using a plasma of one of a carbon-fluoride (CF)-based gas, a CHF-based gas, a nitrogen trifluoride (NF₃) gas, a chlorine (Cl₂) gas, a boron trichlorine (BCl₃) gas and a gas mixture thereof. The CF-based gas basically includes the CF₄ gas and may include an O₂ gas, additionally.

The amorphous C pattern 207A formed over the metal-based hard mask pattern 206A prevents a top attack from the wet or the dry-etch process. Thus, it is possible to laterally etch the metal-based hard mask pattern 206A to adjust the CD.

As described above, since the cell region is protected by the second photoresist pattern 210 and the CD of the metal-based hard mask pattern 206A in the peripheral region is selectively reduced as much as required, an exposure margin of the first photoresist pattern 209 can be secured to form a gate pattern in FIG. 2A. In other words, even though the DICD of the first photoresist pattern 209 increases, the CD of the metal-based hard mask pattern 206A can be reduced as much as needed and thus, the exposure margin is secured to prevent a pattern collapse.

When laterally etching the metal-based hard mask pattern 206A, the CD can be adjusted in consideration of an etch bias generated by a loading effect when etching the gate hard mask layer 205. Thus, a bias gap between the DICD of the first photoresist pattern 209 and the FICD of the etched gate hard mask layer 205 can be decreased.

Referring to FIG. 2D, the second photoresist pattern 210 and the amorphous C pattern 207A are removed using a gas mixture of O₂ and N₂.

Thus, the metal-based hard mask pattern which is not laterally etched remains in the cell region while the laterally etched metal-based hard mask pattern 206A1 having a decreased CD remains in the peripheral region.

Referring to FIG. 2E, the gate hard mask layer 205, the conductive layer 204, and the polysilicon layer 203 are etched to form gate pattern.

In this etch process for forming the gate pattern, the gate hard mask layer 205 is etched by using a gas mixture of a CF-based gas and a CHF-based gas, which may further include an 02 gas and an Ar gas. The CF-based gas includes a CF₄ gas or a hexafluoroethane (C₂F₆) gas. The CHF-based gas includes a fluoroform (CHF₃) gas.

The conductive layer 204 is etched in one of inductively coupled plasma (ICP), decoupled plasma source (DPS), and electron cyclotron resonance (ECR) apparatuses. This etch process is performed by using one of a BCl₃ gas, a CF-based gas, a NFx gas, a SFx gas, and a Cl₂ gas as a main etch gas. Each of the BCl₃ gas, the CF-based gas, the NFx gas, and the SFx gas flows at a rate of approximately 10 sccm to approximately 50 sccm. The Cl₂ gas flows at a rate of approximately 50 sccm to approximately 200 sccm.

In the ICP or the DPS apparatus, the conductive layer 204 is etched by using a source power ranging from approximately 500 W to approximately 2,000 W and adding one of an O₂ gas, a N₂ gas, an Ar gas, a He gas and a gas mixture thereof to the main etch gas. In an ECR apparatus, the conductive layer 204 is etched by using a source power ranging from approximately 1,000 W to approximately 3,000 W and adding one of an O₂ gas, a N₂ gas, an Ar gas, a He gas and a gas mixture thereof to the main etch gas. Herein, the O₂ gas flows at a rate of approximately 1 sccm to approximately 20 sccm; the N₂ gas flows at a rate of approximately 1 sccm to approximately 100 sccm; the Ar gas flows at a rate of approximately 50 sccm to approximately 200 sccm; the He gas flows at a rate of approximately 50 sccm to approximately 200 sccm.

The etched polysilicon layer 203 is called a polysilicon pattern 203A. The etched conductive layer 204 is called a conductive pattern 204A. The etched gate hard mask layer 205 is called a gate hard mask pattern 205A.

If the conductive layer 204 is made of a material substantially the same as that of the metal-based hard mask layer 206, e.g., if both of the metal-based hard mask layer 206 and the conductive layer 204 are made of W, the metal-based hard mask pattern is entirely removed when the process of etching the conductive layer 204 is completed.

If the conductive layer 204 is made of a material different from that of the metal-based hard mask layer 206, e.g., if the metal-based hard mask layer 206 is made of W and the conductive layer 204 does not include W, the remaining metal-based hard mask pattern is removed by an APM cleaning process after the process of etching the conductive layer 204 is completed.

A material having an etch selectivity to the gate insulation layer 202 is used when the polysilicon layer 203 is etched. The etch process is performed by using a Cl₂ gas, an O₂ gas, a HBr gas, and a N₂ gas.

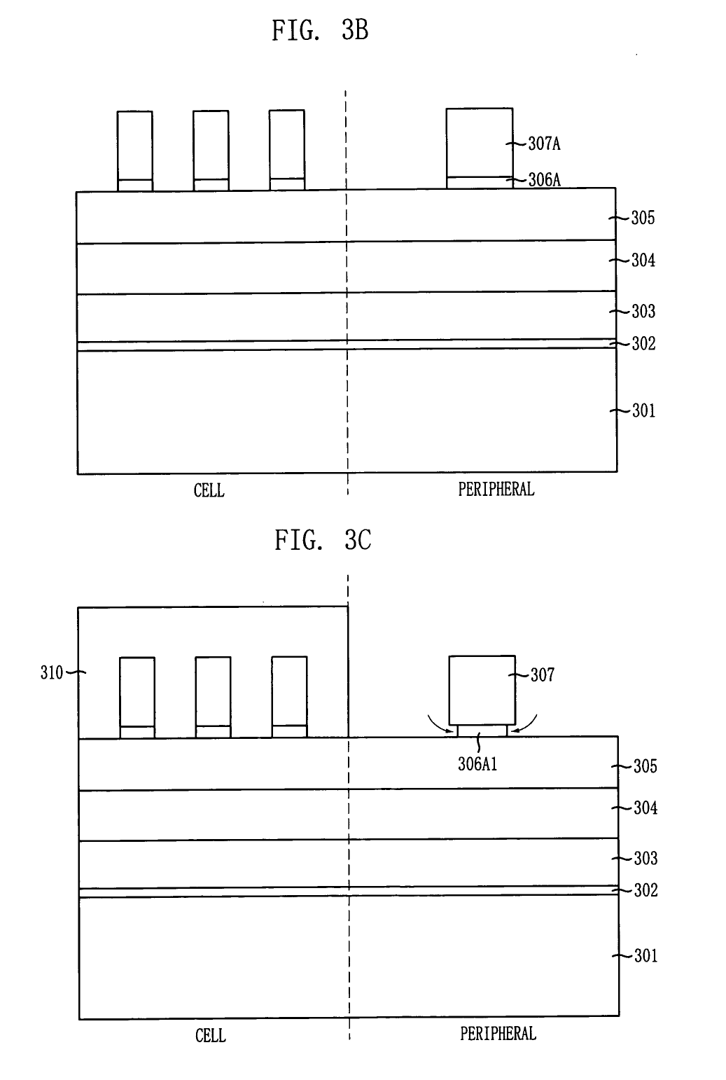

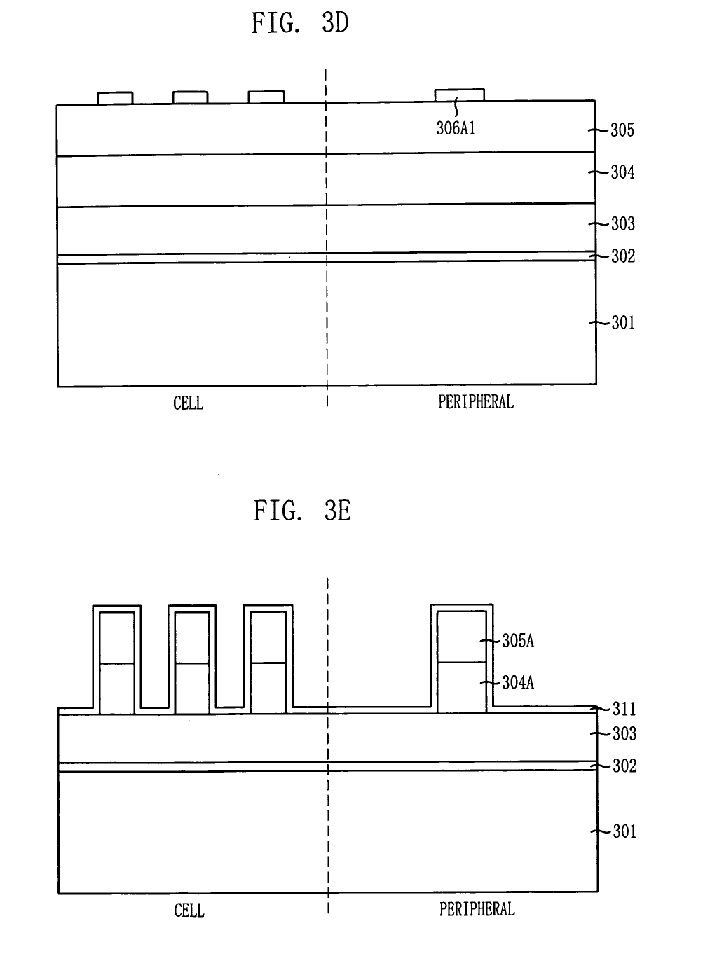

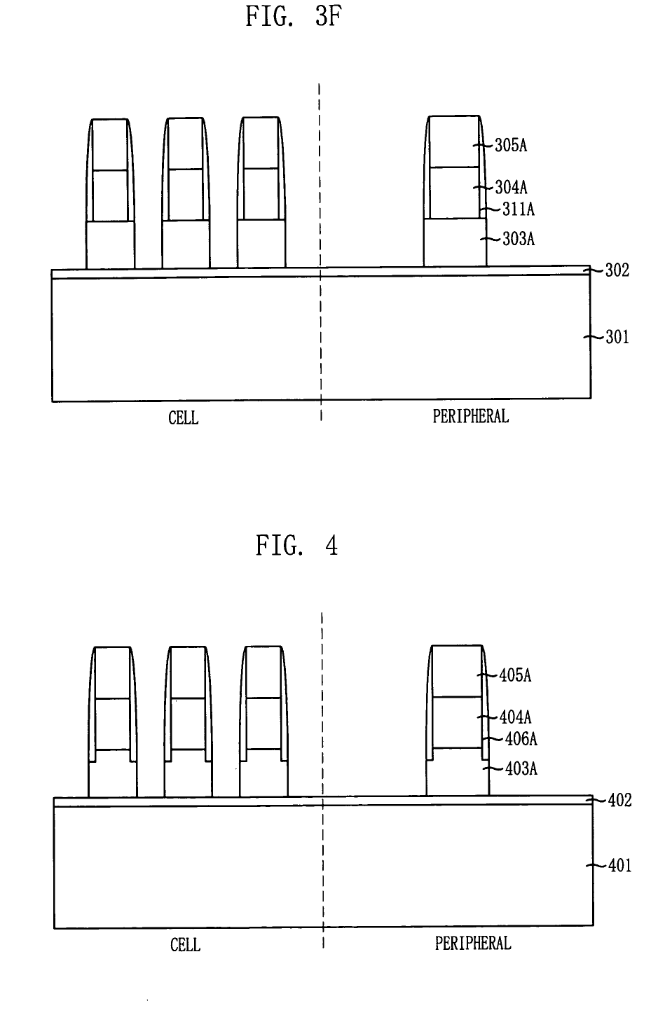

FIGS. 3A to 3F are cross-sectional views of a method for fabricating a semiconductor device in accordance with a second embodiment of the present invention. In the second embodiment, a capping nitride layer is additionally formed to prevent oxidation of the conductive layer 204.

Referring to FIG. 3A, a gate insulation layer 302 is formed over a substrate 301 including a cell region and a peripheral region. The substrate 301 may include a semiconductor substrate on which a DRAM process is to be performed. The gate insulation layer 302 may include an oxide layer. The oxide layer may be a thermal oxide layer or a plasma oxide layer.

A polysilicon layer 303 is formed over the gate insulation layer 302. A conductive layer 304 for an electrode is formed over the polysilicon layer 303. The conductive layer 304 includes a metal layer or a metal silicide layer. The metal layer includes one of W, TiN, and WN layers. The metal silicide layer may include a WSiX layer.

A gate hard mask layer 305 is formed over the conductive layer 304. The gate hard mask layer 305 includes a nitride layer.

A metal-based hard mask layer 306 is formed over the gate hard mask layer 305. The metal-based hard mask layer 306 includes one of W, Ti/TiN, TiCl₄, WN, WSix, and Al₂O₃ layers. In this embodiment, the metal-based hard mask layer 306 includes the W layer.

An amorphous C layer 307 and an ARC layer 308 are formed over the metal-based hard mask layer 306. A first photoresist pattern 309 is formed over the ARC layer 308 to define gate pattern formation regions. The ARC layer 308 includes the SiON layer and prevents a reflection when forming the first photoresist pattern 309. The first photoresist pattern 309 is formed by coating a photoresist layer over the ARC layer 308 and then patterning the photoresist layer by using a photo-exposure and development process to define the gate formation regions in the cell region and in the peripheral region.

Referring to FIG. 3B, the ARC layer 308, the amorphous C layer 307, and the metal-based hard mask layer 306 are sequentially etched.

By using the first photoresist pattern 309, the ARC layer 308 and the amorphous C layer 307 are etched. A gas mixture of O₂, N₂, and H₂ is used for this etch process. When the amorphous C layer 307 is etched, the photoresist layer is also etched by the gas mixture of O₂, N₂, and H₂. Thus, the first photoresist pattern 309 is completely removed when the above process of etching the amorphous C-layer 307 is completed. Hereinafter, the etched amorphous C layer 307 is called an amorphous C pattern 307A.

Subsequently, the metal-based hard mask layer 306 is etched using the amorphous C pattern 307A as an etch mask. The SF₆-based gas or the CF₄ gas is used during this etch process. The SF₆-based gas or the CF₄ gas etches the SiON layer. Thus, the ARC layer 308 is completely removed when the process of etching the metal-based hard mask layer 306 is completed. Hereinafter, the etched metal-based hard mask layer 306 is called a metal-based hard mask pattern 306A.

As the first photoresist pattern 309 and the ARC layer 308 are completely removed, only the amorphous C pattern 307A and the metal-based hard mask pattern 306A remain over the gate hard mask layer 205.

Referring to FIG. 3C, a second photoresist pattern 310 is formed to cover a resultant structure in the cell region described in FIG. 2B while exposing that in the peripheral region. The second photoresist pattern 310 is formed by coating a photoresist layer over a top surface of a resultant structure described in FIG. 2B and then patterning the photoresist layer by using a photo-exposure and development process to leave the photoresist layer only in the cell region.

Then, a process is performed to decrease a CD of the metal-based hard mask pattern 306A in the peripheral region. This is accomplished by wet-etching or dry-etching a sidewall of the metal-based hard mask pattern 306A.

The wet etch process is performed using an APM solution. The APM solution includes NH₄OH, H₂O₂, and H₂O mixed at a ratio of approximately 1:1:5, approximately 1:4:20 or approximately 1:5:50 and has a temperature ranging from approximately 21° C. to approximately 100° C.

The dry etch process is performed using a plasma of one of the CF-based gas, the CHF-based gas, the NF₃, the Cl₂, the BCl₃ and a gas mixture thereof. CF-based gas basically includes the CF₄ gas and may include an O₂gas, additionally.

The amorphous C pattern 307A formed over the metal-based hard mask pattern 306A prevents a top attack from the wet-etch or the dry-etch. Thus, it is possible to laterally etch the metal-based hard mask pattern 306A to adjust the CD.

As described above, since the cell region is protected by the second photoresist pattern 310 and the CD of the metal-based hard mask pattern 306A in the peripheral region is selectively reduced as much as required, an exposure margin of the first photoresist pattern 309 can be secured to form a gate pattern in FIG. 3A. In other words, even though the DICD of the first photoresist pattern 309 increases, the CD of the metal-based hard mask pattern 306A can be reduced as much as needed and thus, the exposure margin is secured to prevent a pattern collapse.

When laterally etching the metal-based hard mask pattern 306A, the CD can be adjusted in consideration of an etch bias generated by a loading effect when etching the gate hard mask layer 305. Thus, a bias gap between the DICD of the first photoresist pattern 309 and the FICD of the etched gate hard mask layer 305 can be decreased.

Referring to FIG. 3D, the second photoresist pattern 310 and the amorphous C pattern 307A are removed using a gas mixture of O₂ and N₂.

Thus, the metal-based hard mask pattern which is not laterally etched remains in the cell region while the laterally etched metal-based hard mask pattern 306A1 having a decreased CD remains in the peripheral region.

Referring to FIG. 3E, the gate hard mask layer 305 and the conductive layer 304 are etched.

In this etch process for forming the gate pattern, the gate hard mask layer 305 is etched by using a gas mixture of a CF-based gas and a CHF-based gas, which may further include an O₂ gas and an Ar gas. The CF-based gas includes a CF₄ gas or the C₂F₆ gas and the CHF-based gas includes the CHF₃ gas.

The conductive layer 304 is etched in one of ICP, DPS, and ECR apparatuses. This etch process is performed by using one of a BCl₃ gas, a CF-based gas, a NFx gas, a SFx gas, and a Cl₂ gas as a main etch gas. Each of the BCl₃ gas, the CF-based gas, the NFx gas, and the SFx gas flows at a rate of approximately 10 sccm to approximately 50 sccm. The Cl₂ gas flows at a rate of approximately 50 sccm to approximately 200 sccm.

In the ICP or the DPS apparatus, the conductive layer 304 is etched by using a source power ranging from approximately 500 W to approximately 2,000 W and adding one of an O₂ gas, a N₂ gas, an Ar gas, a He gas and a gas mixture thereof to the main etch gas. In the ECR apparatus, the conductive layer 304 is etched by using a source power ranging from approximately 1,000 W to approximately 3,000 W and adding one of an O₂ gas, a N₂ gas, an Ar gas, a He gas and a gas mixture thereof to the main etch gas. Herein, the O₂ gas flows at a rate of approximately 1 sccm to approximately 20 sccm; the N₂ gas flows at a rate of approximately 1 sccm to approximately 100 sccm; the Ar gas flows at a rate of approximately 50 sccm to approximately 200 sccm; the He gas flows at a rate of approximately 50 sccm to approximately 200 sccm.

The etched conductive layer 304 is called a conductive pattern 304A for an electrode. The etched gate hard mask layer 305 is called a gate hard mask pattern 305A.

If the conductive layer 304 is made of a material substantially the same as that of the metal-based hard mask layer 306, e.g., if both of the metal-based hard mask layer 306 and the conductive layer 204 are made of W, the metal-based hard mask pattern is entirely removed when the process of etching the conductive layer 304 is completed.

If the conductive layer 304 is made of a material different from that of the metal-based hard mask layer 306, e.g., if the metal-based hard mask layer 306 is made of W and the conductive layer 304 does not include W, the remaining metal-based hard mask pattern is removed by an APM cleaning process after the process of etching the conductive layer 204 is completed.

Subsequently, a capping nitride layer 311 is formed over a resultant structure including the gate hard mask pattern 305A and the conductive pattern 304A. The capping nitride layer 311 is for preventing an abnormal oxidation of the conductive pattern 304A during an oxidation process to be performed after forming a subsequent gate pattern.

Referring to FIG. 3F, the capping nitride layer 311 and the polysilicon layer 303 are etched to form a gate pattern.

The capping nitride layer 311 is etched by using one of NF₃, CF₄, SF₆, Cl₂, O₂, Ar, He, HBr, N₂ gases and a gas mixture thereof. The polysilicon layer 303 is etched by using the Cl₂, the O₂, the HBr and the N₂ gases.

When the forming of the gate pattern is completed, the etched capping nitride layer remains on a sidewall of the gate pattern. Hereinafter, the etched capping nitride layer is called a capping nitride pattern 311A. The etched polysilicon layer is called a polysilicon pattern 303A.

A cleaning process may be performed after the capping nitride layer 311 and the polysilicon layer 303 are etched. The cleaning process is performed by using one of a solvent, a buffered oxide etchant (BOE), and water, and an ozone (03) gas.

In the second embodiment, the capping nitride layer 311 is formed after the conductive pattern 304A is formed. However, the capping nitride layer 311 can be formed after etching a portion of the polysilicon layer 303.

FIG. 4 is a cross-sectional view of a method for fabricating a semiconductor device in accordance with a third embodiment of the present invention.

Referring to FIG. 4, a gate insulation layer 402 is formed over a substrate 401. A gate pattern including sequentially stacked polysilicon pattern 403A, conductive pattern 404A, and gate hard mask pattern 405A is formed over the gate insulation layer 402. A capping nitride pattern 406A is formed over sidewalls of the gate hard mask pattern 405A, the conductive pattern 404A, and an upper portion of the polysilicon pattern 403A.

By also forming the capping nitride layer 406A on the sidewall of the upper portion of the polysilicon pattern 403A, it is possible to prevent abnormal oxidation form occurring at a gap between the polysilicon pattern 403A and the conductive pattern 404A.

This invention employs the metal-based hard mask layer 206 to form the gate pattern and selectively decreases the CD of the metal-based hard mask pattern 206A in the peripheral region. Thus, the exposure margin of the first photoresist pattern 209 is secured. In other words, in accordance with the present invention, even though the first photoresist pattern 209 is formed to have a large DICD, the CD of the metal-based hard mask pattern 206A can be reduced as much as needed. Thus, the exposure margin is secured, and it is possible to prevent the pattern collapse.

It is possible to adjust the CD in consideration of an etch bias generated by a loading effect when etching the gate hard mask layer 205. Thus, a bias gap between the DICD of the first photoresist pattern 209 and the FICD of the etched gate hard mask layer 205 can be reduced.

The amorphous C layer 207 formed over the metal-based hard mask layer 206 can prevent the top attack when performing the lateral-etch of the metal-based hard mask pattern 206A.

The capping nitride layer formed on the sidewall of the gate pattern can prevent the abnormal oxidation of the conductive layer during the subsequent gate oxidation.

Above embodiments describe an application of forming a gate pattern. The spirit and the scope of the present invention can be applied to any processes for forming other patterns, e.g., a bit line pattern.

While the present invention has been described with respect to the specific embodiments, it will be apparent to those skilled in the art that various changes and modifications may be made without departing from the spirit and scope of the invention as defined in the following claims.

What is claimed is:

1. A method for fabricating a semiconductor device, the method comprising:
providing a substrate where a cell region and a peripheral region are defined;
stacking a conductive layer, a hard mask layer, a metal-based hard mask layer, and an amorphous carbon (C) pattern over the substrate;
etching the metal-based hard mask layer using the amorphous C pattern as an etch mask, thereby forming a resultant structure;
forming a photoresist pattern covering the resultant structure in the cell region while exposing the resultant structure in the peripheral region;
decreasing a width of the etched metal-based hard mask layer in the peripheral region;
removing the photoresist pattern and the amorphous C pattern; and
forming a conductive pattern by etching the hard mask layer and the conductive layer using the etched metal-based hard mask layer as an etch mask.

2. The method of claim 1, wherein the metal-based hard mask layer includes one of a tungsten (W) layer, a titanium (Ti)/titanium nitride (TiN) layer, a titanium tetrachloride (TiCl₄) layer, a WN layer, a tungsten silicide (WSix) layer, and an alumina (Al₂O₃ ) layer.

3. The method of claim 2, wherein decreasing the width of the etched metal-based hard mask layer is performed by a wet-etch or a dry-etch process.

4. The method of claim 3, wherein the wet-etch process is performed by using an ammonium hydroxide-peroxide mixture (APM) solution including ammonia water (NH₄OH), hydrogen peroxide (H₂O₂) and H₂O mixed at a ratio of approximately 1:1:5, approximately 1:4:20 or approximately 1:5:50.

5. The method of claim 4, wherein the APM solution has a temperature ranging from approximately 21° C. to approximately 100° C.

6. The method of claim 3, wherein the dry-etch process is performed by using a plasma of one of a carbon-fluoride (CF)-based gas, a CHF-based gas, a nitrogen trifluoride (NF₃) gas, a chlorine (Cl₂) gas, a boron trichlorine (BCl₃) gas and a gas mixture thereof.

7. The method of claim 6, wherein the CF-based gas includes a tetrafluoromethane (CF₄) gas added to an oxygen (O₂) gas.

8. The method of claim 1, wherein etching the metal-based hard mask layer is performed by using a gas mixture of a CF-based gas and a CHF-based gas added with an O₂ gas or an argon (Ar) gas.

9. The method of claim 8, wherein the CF-based gas includes a CF₄ gas or a C₂F₆ gas and the CHF-based gas includes a fluoroform (CHF₃) gas.

10. The method of claim 1, wherein the conductive layer has a stack structure of a polysilicon layer and a metal or a metal silicide layer, wherein the metal or metal silicate layer includes one of a W layer, a WN layer, a WSiX layer, and a TiN layer.

11. The method of claim 1, wherein etching the conductive layer is performed by using one of a BCl₃ gas, a CF-based gas, a NFx gas, a SFx gas, and a Cl₂ gas as a main etch gas in one of inductively coupled plasma (ICP), decoupled plasma source (DPS), and electron cyclotron resonance (ECR) apparatuses.

12. The method of claim 11, wherein each of the BCl₃ gas, the CF-based gas, the NFx gas and the SFx gas flows at a rate of approximately 10 sccm to approximately 50 sccm and the Cl₂ gas flows at a rate of approximately 50 sccm to approximately 200 sccm.

13. The method of claim 11, wherein etching the conductive layer is performed in the ICP apparatus or the DPS apparatus by supplying a source power ranging from approximately 500 W to approximately 2,000 W and adding one of an O₂ gas, a N₂ gas, an Ar gas, a He gas and a gas mixture thereof to the main etch gas.

14. The method of claim 11, wherein etching the conductive layer is performed in the ECR apparatus by supplying a source power of approximately 1,000 W to approximately 3,000 W and adding one of an O₂ gas, a N₂ gas, an Ar gas, a He gas and a gas mixture thereof to the main etch gas.

15. The method of claim 13, wherein the O₂ gas flows at a rate of approximately 1 sccm to approximately 20 sccm, the N₂ gas flows at a rate of approximately 1 sccm to approximately 100 sccm, the Ar gas flows at a rate of approximately 50 sccm to approximately 200 sccm, and the He gas flows at a rate of approximately 50 sccm to approximately 200 sccm.

16. The method of claim 1, wherein the conductive layer is made of the same material as the metal-based hard mask layer and the metal-based hard mask layer is removed when the conductive layer is etched.

17. The method of claim 1, further comprising:
removing the etched metal-based hard mask layer after etching the conductive layer when the conductive layer is made of a material different from that of the metal-based hard mask layer.

18. The method of claim 17, wherein removing the etched metal-based hard mask layer is performed by an APM cleaning process.

19. The method of claim 1, wherein the conductive layer includes a polysilicon layer and a metal or metal silicide layer, and forming the conductive pattern comprises:
etching the hard mask layer and the metal or metal silicide layer;
forming a capping nitride layer over a surface of a resultant structure including the etched hard mask layer and the etched metal or metal silicide layer;
etching the capping nitride layer to form a capping nitride pattern on sidewalls of the etched hard mask layer and the etched metal or metal silicide layer; and
etching the polysilicon layer.

20. The method of claim 19, wherein etching the capping nitride layer is performed by using one of a NF₃ gas, a CF₄ gas, a SF₆ gas, a Cl₂ gas, a O₂ gas, an Ar gas, a He gas, a HBr gas, a N₂ gas and a gas mixture thereof.

21. The method of claim 1, wherein the conductive layer includes a polysilicon layer, the method further comprising etching the polysilicon layer using a Cl₂ gas, an O₂ gas, a HBr gas and a N₂ gas.

22. The method of claim 19, further comprising performing a cleaning process after etching the polysilicon layer.

23. The method of claim 22, wherein the cleaning process is performed by using one of a solvent, a buffered oxide etchant (BOE), and water, and an ozone (O₃) gas.

24. The method of claim 10, wherein forming the conductive pattern comprises:
etching the hard mask layer and the metal or metal silicide layer;
etching an upper portion of the polysilicon layer;
forming a capping nitride layer over a surface of a resultant structure including the etched hard mask layer, the etched metal or metal silicide layer and the partially etched polysilicon layer;
etching the capping nitride layer to form a capping nitride pattern on sidewalls of the etched hard mask layer, the etched metal or metal silicide layer and the etched upper portion of the polysilicon layer; and
etching the remaining portion of the polysilicon layer.

25. A method for fabricating a semiconductor device, the method comprising:
forming a gate insulation layer over a substrate including a cell region and a peripheral region;
forming a metal-based hard mask layer over the substrate;
forming an amorphous C layer over the metal-based hard mask layer;
etching the amorphous C layer to form an amorphous C pattern;
etching the metal-based hard mask layer using the amorphous C pattern forming a metal-based hard mask pattern;
forming a photoresist pattern to cover a resultant structure in the cell region while exposing the peripheral region;
etching a sidewall of the metal-based hard mask pattern to decrease a critical dimension (CD) of the metal-based hard mask pattern in the peripheral region.

26. The method of claim 25, further comprising:
forming a polysilicon layer over the gate insulation layer;
forming a conductive layer over the polysilicon layer;
forming a conductive pattern by etching the conductive layer using the metal-based hard mask pattern.

27. The method of claim 26, wherein the conductive layer includes the polysilicon layer and a metal or metal silicide layer, and forming the conductive pattern comprises:
forming a hard mask layer over the conductive layer;
etching the hard mask layer and the metal or metal silicide layer;
forming a capping nitride layer over a surface of a resultant structure including the etched hard mask layer and the etched metal or metal silicide layer;
etching the capping nitride layer to form a capping nitride pattern on sidewalls of the etched hard mask layer and the etched metal or metal silicide layer; and
etching the polysilicon layer.
